(19) United States
(12) Patent Application Publication
(10) Pub. No.: US 2016/0336897 A1
(43) Pub. Date: Nov. 17, 2016

(54) Apparatus for Sunlight Collection and Solar Energy Generation

(71) Applicant: Michael Xiaoxuan Yang, Palo Alto, CA (US)

(72) Inventor: Michael Xiaoxuan Yang, Palo Alto, CA (US)

(21) Appl. No.: 15/175,737

(22) Filed: Jun. 7, 2016

Related U.S. Application Data
(60) Provisional application No. 62/274,876, filed on Jan. 5, 2016.

(51) Int. Cl. H02S 20/32; H01L 31/054

(52) U.S. Cl. CPC H02S 20/32; H01L 31/0547; H01L 31/0543

(57) ABSTRACT

This invention relates to photovoltaic (PV) systems with solar trackers. Retractable auxiliary panels are positioned at opposite sides of a solar panel along its tilt direction. The auxiliary panels do not obstruct the direct solar irradiation onto the solar panels, but rather redirect additional solar irradiation to the solar panels, including both direct beam and diffuse sunlight. While solar panels tilt to track the sun, configurations of the auxiliary panels can be adjusted to avoid shading on adjacent solar panels. Compared to conventional PV systems on solar trackers, the proposed PV system can significantly improve overall sunlight collection and PV system output throughout a day.

### CROSS REFERENCE TO RELATED APPLICATION

The present invention claims priority to U.S. Provisional Application No. 62/274,876 filed Jan. 5, 2016.

### FIELD OF THE INVENTION

The present invention relates to solar energy systems to convert solar irradiation to electricity, including photovoltaic (PV) and concentrator photovoltaic (CPV) systems.

### BACKGROUND OF THE INVENTION

Photovoltaics (PV) or concentrator photovoltaics (CPV) systems can generate electricity from solar irradiation. In PV systems, solar panels convert light directly into electric currents. In comparison, CPV systems use lenses or mirrors to focus solar irradiation over a large area into a small beam before high-efficiency solar cells converting the sunlight to electricity.

PV modules in use include both rigid flat panels and flexible modules. Flat panel modules dominate worldwide PV market and most flat-panel PV modules consist of crystalline silicon (c-Si) solar cells. Currently crystalline silicon solar panels accounts for more than 90 percent of overall worldwide PV production. The c-Si solar panels are assembled with c-Si solar cells sandwiched between a back sheet and a transparent front cover, e.g. glass. The sunlight to electricity conversion rate, a.k.a. module efficiency, can exceed 15% for multicrystalline silicon solar panels, and >20% for monocrystalline silicon solar panels. The rest of the PV panel production include flat-panel PV modules based on cadmium telluride (CdTe), copper indium gallium selenide (CIGS) or amorphous silicon(a-Si)/microcrystalline silicon (μc-Si) photoactive thin films materials. Thin film solar cells and modules are constructed on the same production line, as photoactive thin film and other layers in the cell structure are deposited on a substrate or superstrate, e.g. a glass, and subsequently encapsulated, e.g. by another glass. The module efficiency can be >15% for CdTe and CIGS solar panels, and >12% for a-Si/μc-Si solar panels in current commercial production, respectively. The highest solar panel efficiency has been demonstrated on high-cost, multi-junction solar cells based on compound semiconductors such as gallium arsenide (GaAs). The module efficiency can be >35% for stand-alone multi-junction GaAs based PV panels, and >40% in concentrator photovoltaic (CPV) configurations.

Different from rigid flat-panel solar modules, flexible solar modules are fabricated by constructing solar cells on a flexible substrate before laminating a transparent encapsulation layer on top. Flexible photovoltaics were first developed based on conventional thin film solar materials such as CdTe, CIGS and a-Si/μc-Si. New technology development in flexible PV includes novel materials such as dye-sensitized solar cells and organic solar cells.

Flexible solar modules can be well suited for emerging applications including portable chargers and building integrated photovoltaics. In comparison, rigid solar panels have advantages in high efficiency, low cost and proven lifetime. They have dominated mainstream residential, commercial and utility markets.

Energy production of PV systems is proportional to amount of sunlight collection. There are two components in sunlight reaching the earth surface: the “direct beam” that carries about 90% of the solar energy on a clear day, and the “diffuse sunlight” that carries the remainder. As the majority of the solar energy is in the direct beam, maximizing sunlight collection requires a direct line-of-sight of solar modules to the Sun. Angle of incidence (a.k.a. incidence angle) on solar module is 0 degree for irradiation from surface normal direction and 90 degrees for irradiation from surface glancing direction. Solar irradiation intensity is proportional to cosine of the angle of incidence. As a result, irradiation intensity decreases with an increase in angle of incidence.

Energy production of PV systems is also proportional to solar module efficiency. Solar module efficiency can be a function of irradiation intensity. In general crystalline silicon solar cell efficiency improves with an increase in irradiation intensity up to 1 Sun. With an optimization of cell structure design and manufacturing processes, cell efficiency can further improve in CPV configurations, i.e. under an irradiation intensity exceeding 1 Sun. As illustrated in FIG. 1, cell efficiency of representative backside contact crystalline silicon solar cells improves with an increase in solar irradiation intensity, up to ˜7 Suns at normal incidence.

Solar module efficiency can also be a function of the incidence angle under a normalized irradiation energy. As shown in FIG. 2, crystalline silicon solar module efficiency can decline significantly with an incidence angle of >60 degrees under a fixed irradiation intensity (after calibration of incidence angle). Some of the decline can be attributed to an increase in light reflection off solar module front cover glass at a significant incidence angle.

Residential and small-scale commercial photovoltaic panels are usually mounted at a fixed angle on rooftops. Solar panels on a fixed mount can collect diffuse sunlight from all directions. However, solar panels on a fixed mount do not track the sun, and can be limited in direct beam solar irradiation collection and energy production throughout a day. The sun travels through ˜180 degrees from east to west during a ˜½ day period (more in summer and less in winter). Local horizon effects can reduce the effective motion to ˜150 degrees. As a result, solar panels fixed in a nearly horizontal orientation can have a misalignment of 75 degrees to sunlight direct beam direction at the dawn and sunset extremes, leading to a ˜75% reduction in direct beam solar irradiation intensity. In addition, solar module efficiency can drop significantly with not only the increase in incidence angle but also the decrease in solar irradiation intensity. Consequently, the overall electricity generation can be significantly handicapped for solar panels at a fixed orientation throughout a day.

In order to maximize PV system energy production, a vast majority of large scale commercial PV installations greater than one megawatt have adopted solar trackers. A solar tracker is a device that orients a payload toward the sun. Payloads can include flat solar panels in standard PV systems as well as parabolic troughs, Fresnel reflectors, mirrors or lenses in CPV systems. Solar trackers can significantly improve PV system efficiency. For instance, rotating solar panels from east to west can help to capture most of the sunlight throughout a day, thus maximize energy produced from a fixed number of solar panels.

A solar tracker with one degree of freedom (rotating solar panels from east to west) is known as a single-axis solar tracker. There are several common implementations of single axis solar trackers, including horizontal single axis trackers (HSAT), horizontal single axis trackers with tilted modules (HTSAT), vertical single axis trackers (VSAT), tilted single axis trackers (TSAT) and polar aligned single axis trackers (PSAT).

Single axis trackers can follow the solar angle change throughout a day, but do not recoup the energy loss due to the seasonal change of the solar angle. The sun moves through 46 degrees from north to south in a year. As a result, solar panels oriented at the midpoint between the two seasonal extremes at each geographic location can see the Sun move a maximum of 23 degrees on either side throughout a year, leading to an additional solar irradiation energy loss of ˜8%. The loss in system output due to the seasonal solar angle change can be further complicated by changes in the length of day throughout a year. With more sunlight to collect throughout a day in the summer in northern or southern hemispheres, solar panels can be positioned closer to the average solar angle in the summer. In this way the total sunlight collection throughout a year can be improved in comparison with a PV system aligned at the spring/fall solstice angle (which is the same as the site's latitude).

A solar tracker that can follow both solar daily (from east to west) and seasonal (between north and south) motions is known as a dual-axis solar tracker. Dual axis trackers have two degrees of freedom that act as axes of rotation. These axes are typically normal to one another. One axis is fixed with respect to the ground and can be considered as the primary axis. The other axis is referenced to the primary axis and can be considered as the secondary axis. Dual axis trackers typically have modules oriented parallel to the secondary axis of rotation. Dual-axis trackers can be classified by the orientation of their primary axis with respect to the ground. Two common implementations of dual axis solar trackers are tip-tilt dual axis trackers (TTDAT) and azimuth-altitude dual axis trackers (AADAT).

Compared with single-axis solar trackers, double-axis solar trackers can adjust the solar panel tilt not only at different time in a day but also in different seasons of a year. No matter where the sun is in the sky, dual axis trackers are able to angle the solar panels to a direct alignment with the sun. However, adoption of double-axis solar trackers requires clearance at both sides of solar panels in both tilt directions, i.e. all four sides of solar panels. In comparison, PV systems on single-axis solar trackers require clearance at both sides in only one tilt direction. FIGS. 3 and 4 illustrate some conventional PV systems with solar trackers. FIG. 3 illustrates a PV system with rows of solar panels 101. The system can be equipped with single-axis solar trackers. FIG. 4 illustrates another PV system with an array of solar panels 201. The system can be equipped with dual-axis solar trackers. As shown in the figures, PV systems with double-axis solar trackers can often accommodate less numbers of solar panels than PV systems with single-axis solar trackers over the same land area.

FIG. 5 illustrated configuration changes of a PV system with rows of solar panels on single-axis solar trackers throughout a day. Solar panels 101 can be tilted at different angles to follow the sun from east to west, i.e. from left to right in the figure. A solar panel tilt angle A301 can be defined for solar panels 101 with reference to ground 110. The solar panel tilt angle is zero with the solar panel oriented parallel to the ground, and 90 degrees with the solar panel oriented perpendicular to the ground. As shown in FIG. 5, in a normal operation of PV systems mounted on solar trackers, the solar panel tilt angle A301 is nearly zero at noon time (FIG. 5“D”), and at maximum in early morning (FIG. 5“A”) and late afternoon (FIG. 5“G”).

Solar cells are wired into series circuits in a solar panel, thus power output is limited by the current passing through the weakest cell. In addition, when one cell or a group of cells generate a significantly smaller amount of power than the rest of the cells in the series circuit, the cell(s) can suffer from thermal stress (i.e. overheating) and the power output of the solar panel can be further reduced. As a result, shading on a small section of a solar panel can significantly reduce the performance of the entire panel. As the solar panel tilt angle changes to follow the sun throughout a day, shading on adjacent solar panels must be avoided.

Ground coverage ratio (GCR) is an important parameter in the design of photovoltaic (PV) systems with solar trackers. Ground coverage ratio is defined as the area of PV modules divided by the total land area occupied by the PV system. For PV systems with rows of solar panels on single-axis trackers, ground coverage ratio can be simply calculated from the width of the PV modules and the spacing between adjacent rows. In order to prevent shading on the adjacent solar panels at the maximum tilt of solar panels, there is a trade-off between maximum tilt angle of solar panels and system ground coverage ratio, as the maximum solar panel tilt angle sets an upper limit on the system ground coverage ratio. For instance, FIG. 5 illustrates configurations of a PV system on single-axis trackers with a maximum solar panel tilt angle of 60 degrees (FIG. 5“A” and FIG. 5“G”) with a maximum ground coverage ratio of 50%, i.e. a spacing between rows of solar panels equal to the width of the rows.

As shown in FIG. 5“D”, the solar panel tilt angle A301 is nearly zero near noon time. For instance, at a system ground coverage ratio of 50%, only half of the direct beam solar irradiation on the entire land area is captured by solar panels at noon time. In practice, many solar projects have a ground coverage ratio considerably less than 50%. The smaller the PV system ground coverage ratio is, the less efficient collection of solar irradiation over the entire project land area is throughout a day. Subsequently, the overall PV system output throughout a day can be constrained.

The present invention circumvents the trade-off between maximum solar panel tilt angle and maximum ground coverage ratio in the conventional PV systems. With no change in the PV system ground coverage ratio and maximum solar panel tilt angle, PV systems according to this invention can collect more sunlight on the solar panels and generate more electricity throughout a day.

The present invention is also related with concentrator photovoltaics (CPV) systems. FIG. 6 illustrates two conventional configurations of CPV systems. In the first basic CPV system configuration as shown in FIG. 6A, solar cells can be positioned with their active surface 201A facing against the Sun, with a reflector 202 placed behind the plane of solar cells to reflect and focus direct beam sunlight to solar cell active surface 201A. In the second basic CPV system configuration as shown in FIG. 6B, solar cells can be positioned with their active surface 201A facing toward the Sun, with a lens 203 placed in front of the plane of solar cells to transmit and focus direct beam sunlight to the solar cell active surface 201A. In both basic configurations of CPV systems, the relative configuration is fixed between the concentrator (reflectors in FIG. 6A and lens in FIG. 6B) and the collector (solar cells). Compared with standard PV systems, CPV systems require a more precise alignment to the Sun. In addition, conventional CPV systems do not collect and utilize diffuse sunlight for energy generation.

The PV systems according to this invention are different from standard CPV systems. Significant amount of diffuse sunlight can be captured and no high-precision solar tracker is required in the proposed PV systems.

### SUMMARY OF THE INVENTION

The present invention relates to PV systems with solar trackers. Auxiliary panels are positioned at opposite sides of a solar panel along its tilt direction. The auxiliary panels do not obstruct line-of-sight of the solar panel to the sun. Rather, the auxiliary panels redirect additional sunlight to the solar panel. The auxiliary panels are retractable, and the system can have further capabilities to adjust tilt angle of the auxiliary panels with reference to the solar panel. The entire auxiliary panel mechanism can be mounted on the solar trackers, and the mechanical controls of the auxiliary panels can be coordinated with those of the solar panel. Solar panels on a solar tracker orient nearly horizontal near noon time, and the auxiliary panels can extend fully for maximum sunlight collection. In the morning and afternoon, the solar panels tilt to track the sun, and extension of the auxiliary panels can be reduced to avoid shading on the adjacent solar panels. The tilt angles of the auxiliary panels with reference to the solar panels can also be adjusted accordingly.

### BRIEF DESCRIPTIONS OF THE DRAWINGS

Embodiments are illustrated in the following detailed description and are not limited in the following figures.

FIG. 1 illustrates a representative response of backside contact crystalline silicon solar cell efficiency as a function of irradiation intensity.

FIG. 2 illustrates a representative response of crystalline silicon solar module efficiency as a function of angle of incidence (AOI) of solar irradiation.

FIG. 3 illustrates a perspective view of a conventional photovoltaic (PV) system with rows of solar panels. The rows of solar panels can be mounted on single axis solar trackers, and line up in a general North-South direction.

FIG. 4 illustrates a perspective view of a conventional PV system with a solar panel array, and each solar panel can comprise of multiple panels connected together. The solar panels can be mounted on dual axis solar trackers.

FIG. 5 illustrates a diagrammatic cross section view of a conventional PV system on single-axis solar trackers. Solar panel tilt angle changes throughout a day to follow the Sun.

FIG. 6 illustrates a diagrammatic cross-section view of two basic configurations of conventional concentrator photovoltaic (CPV) systems.

FIG. 7 illustrates a perspective view of a PV system with rows of solar panels on single-axis solar trackers with retractable auxiliary panels, according to the present invention. Two retractable auxiliary panels are positioned at opposite sides of each row of the solar panels.

FIG. 8 illustrates a perspective view of a PV system comprising of a solar panel array on double-axis solar trackers with retractable auxiliary panels, according to the present invention. Retractable auxiliary panels are positioned at all four sides of each solar panel.

FIG. 9 illustrates a diagrammatic cross-section view of two basic configurations of a solar panel with retractable auxiliary panels positioned at opposite sides of the solar panel, according to the present invention. Curved auxiliary panels 102T and 103T transmit additional sunlight to the solar panel 101, and planar auxiliary panels 102 and 103 reflect additional sunlight to the solar panel 101.

FIG. 10 illustrates a diagrammatic cross-section view of a retractable auxiliary panel 103 (103R, 103RR) positioned next to a solar panel 101, according to the present invention. Auxiliary panel tilt angle A303 decreases with a reduction in extension of auxiliary panel in front of plane of solar panel 111.

FIG. 11 illustrates a diagrammatic cross-section view of solar panels with auxiliary panels at opposite sides of the solar panels, according to the present invention. Solar panels 101 are tilted to follow the Sun. Auxiliary panels 102 and 103 are positioned at opposite sides of solar panels 101 with matching extensions/tilt angles, and are configured to avoid shading on solar panels.

FIG. 12 illustrates a diagrammatic cross-section view of a PV system mounted on single-axis solar trackers with planar reflective auxiliary panels, according to the present invention. Solar panels 101 tilt at different angles to follow the Sun at different times of the day. Retractable auxiliary panels 102 and auxiliary panels 103 are positioned at opposite sides of solar panels 101 with matching extensions and tilt angles. Extension of auxiliary panels and auxiliary panel tilt angles are adjusted according to the change in solar panel tilt angle A301 to avoid shading on adjacent solar/auxiliary panels.

FIG. 13 illustrates a diagrammatic cross-section view of three configurations of a PV system with retractable planar reflective auxiliary panels, according to the present invention. Solar panels 101 are tilted to follow the sun. Configurations of auxiliary panels at opposite sides of solar panels 101 are coordinated to avoid shading on adjacent solar panels/auxiliary panels. FIGS. 13“A”, 13“B” and 13“C” illustrate three different combinations of auxiliary panel extensions and tilt angles.

FIG. 14 illustrates a diagrammatic cross-section view of three configurations of a PV system with retractable planar reflective auxiliary panels, according to the present invention. Solar panels 101 are tilted to follow the sun. Extension and tilt angles of auxiliary panels at the left side (higher side of solar panels) 102 are configured to avoid shading on adjacent solar panels. Auxiliary panels at the right side (lower side of solar panels) 103 are out of sight from the sun but reflect diffuse sunlight to the solar panels 101, according to the present invention.

FIG. 15 illustrates a diagrammatic cross-section view of a PV system mounted on single-axis solar trackers with retractable planar reflective auxiliary panels, according to the present invention. Solar panels 101 tilt at different angles to follow the sun at different times of a day. Extensions of auxiliary panels at opposite sides of solar panels and auxiliary panel tilt angles are adjusted accordingly. FIG. 15“A”: Solar panel tilt angle is zero. Auxiliary panels 102 and auxiliary panels 103 have matching extensions and auxiliary panel tilt angles. FIG. 15“B”: Solar panel tilt angle A301B increases with no change in extension of auxiliary panels at the left side (higher side of solar panels) 102 and corresponding auxiliary panel tilt angle A302. Part of auxiliary panels at the right side (lower side of solar panels) 103B-1 have line of sight to the sun while the rest of auxiliary panels 103B-2 are out of sight from the sun, and auxiliary panel tilt angle A303B is reduced accordingly. FIG. 15“C”: An additional increase in solar panel tilt angle A301C with no change in extension of auxiliary panels at the left side (higher side of solar panels) 102 and corresponding auxiliary panel tilt angle A302. Auxiliary panels at the right side (lower side of solar panels) 103C are out of sight from the Sun, and are configured to redirect diffuse sunlight to solar panels 101. FIG. 15“D”: Solar panel tilt angle A301D increases further. Extension of auxiliary panels at the left side (higher side of solar panels) 102D is reduced to avoid shading on adjacent solar panels, and auxiliary panel tilt angle A302D is reduced accordingly. Auxiliary panels at the right side (lower side of solar panels) 103D are out of sight from the sun and are configured to redirect diffuse sunlight to solar panels 101. FIG. 15“E”: Solar panels 101 are tilted at a maximum solar panel tilt angle A301E. Auxiliary panels at the higher side (left side) of solar panels are fully retracted. Auxiliary panels at the right side (lower side of solar panels) 103E are out of sight from the sun and are configured to redirect diffuse sunlight to solar panels 101.

FIG. 16 illustrates a diagrammatic cross-section view of a PV system mounted on single-axis solar trackers with retractable planar reflective auxiliary panels, according to the present invention. Solar panels 101 tilt at different angles to follow the sun at different times of a day. Extensions of auxiliary panels at opposite sides of solar panels and auxiliary panel tilt angles are adjusted accordingly. FIG. 16“A”: Solar panel tilt angle is zero. Auxiliary panels 102 and auxiliary panels 103 have matching extensions/tilt angles. FIG. 16“B”: Solar panel tilt angle A301B increases with no change in extension of auxiliary panels at the right side (lower side of solar panels) 103 and corresponding auxiliary panel tilt angle A303. Auxiliary panels at the left side (higher side of solar panels) 102B retract to avoid shading on adjacent solar panels, and auxiliary panel tilt angle A302B is reduced accordingly. FIG. 16“C”: An additional increase in solar panel tilt angle A301C with no change in extension of auxiliary panels at the right side (lower side of solar panels) 103 and corresponding auxiliary panel tilt angle A303. The auxiliary panels at the higher side (left side) of solar panels are fully retracted. FIG. 16“D”: Solar panel tilt angle A301D increases further. Part of auxiliary panels at the right side (lower side of solar panels) 103D-1 have line of sight to the sun while the rest of auxiliary panels 103D-2 are out of sight from the sun, and auxiliary panel tilt angle A303D is reduced accordingly. The auxiliary panels at the higher side (left side) of solar panels are fully retracted. FIG. 16“E”: Solar panels 101 are tilted at the maximum tilt angle A301E. Auxiliary panels at the right side (lower side of solar panels) 103E are fully out of sight from the Sun and redirect diffuse sunlight to solar panels 101. Auxiliary panels at the higher side (left side) of solar panels are fully retracted.

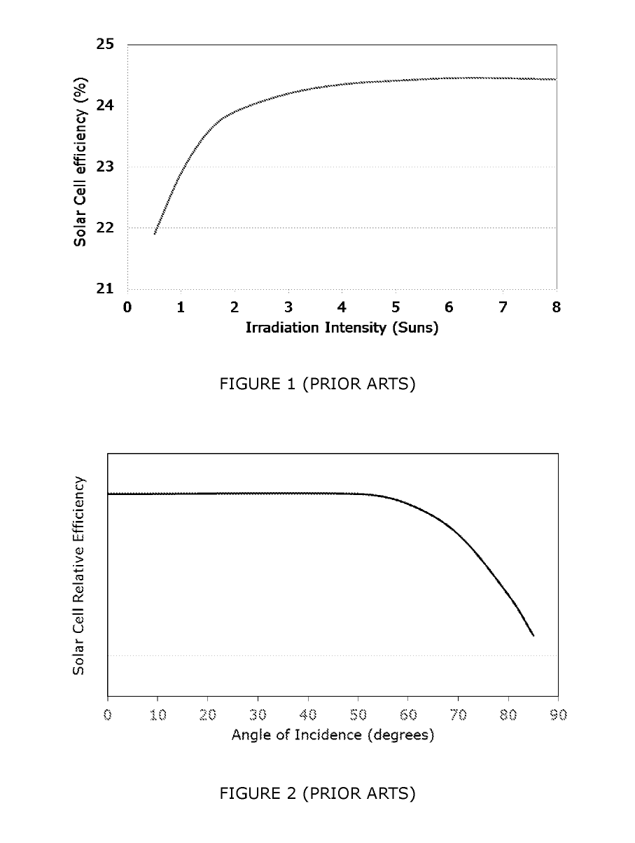

### DETAILED DESCRIPTION OF THE PREFERRED EMBODIMENTS

The present invention is applicable to PV systems with solar trackers. As discussed in Background of the Invention section, solar trackers can tilt solar panels to follow the sun. They are common in large size commercial and utility PV systems. In this invention, retractable auxiliary panels are positioned at opposite sides of a solar panel along its tilt direction. The auxiliary panels redirect additional sunlight to the solar panel. As a result, the total sunlight collection onto the solar panel is increased, en route to a boost in PV system output.

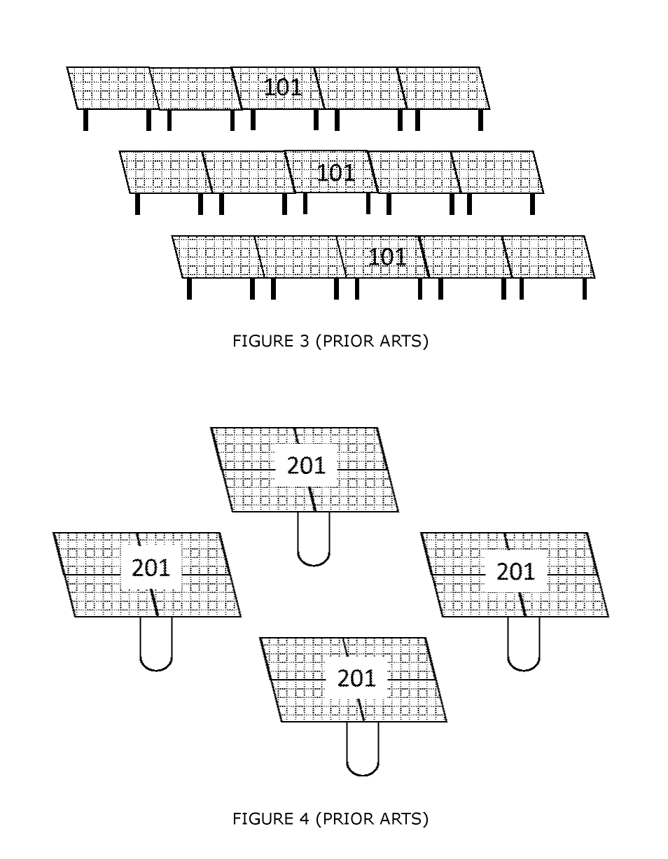

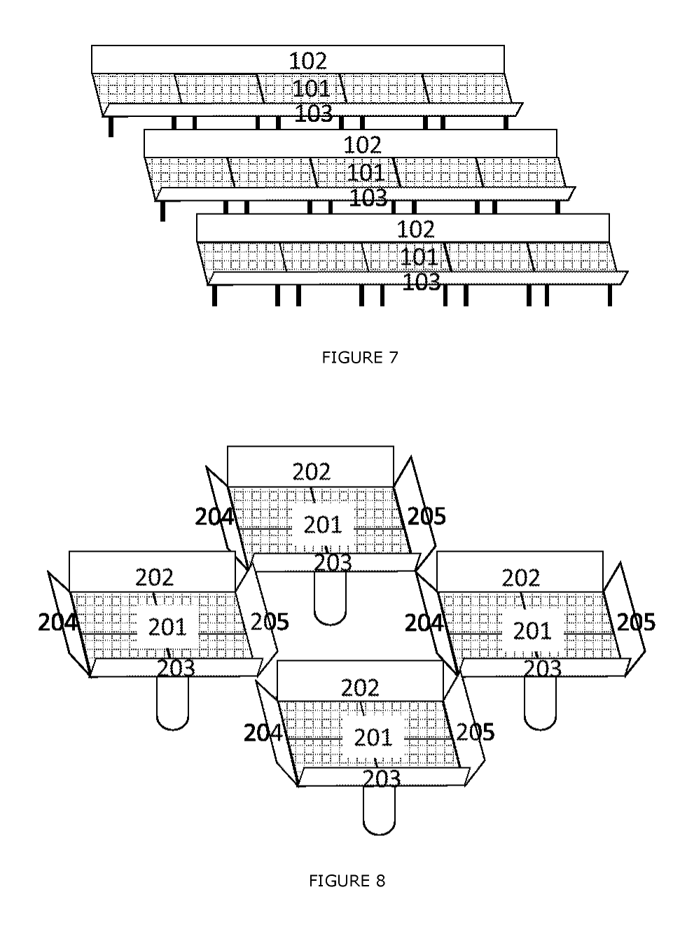

FIGS. 7 and 8 provide perspective views of PV systems with the auxiliary panels according to the present invention, with reference to conventional PV systems shown in FIGS. 3 and 4. As shown in FIG. 7, auxiliary panels 102 and 103 can be positioned at two opposite sides of solar panels 101 on single-axis solar trackers. Meanwhile, as shown in FIG. 8, auxiliary panels 202/203/204/205 can be positioned at four sides of discrete solar panels 201 on double-axis solar trackers.

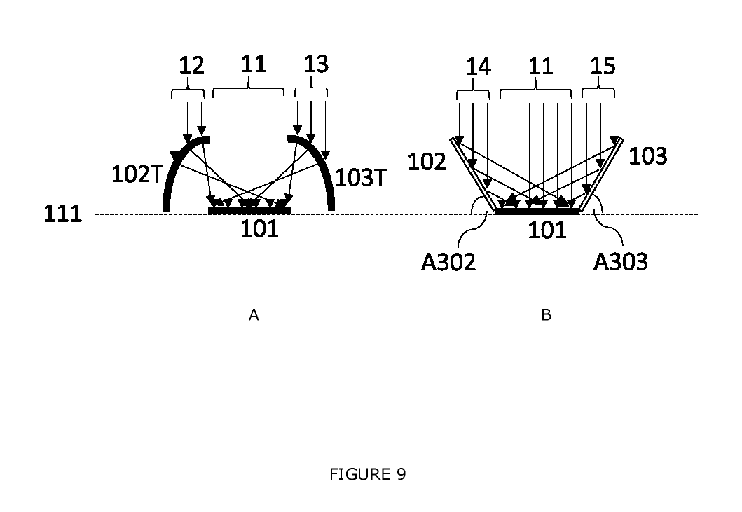

FIG. 9A and FIG. 9B illustrate two basic configurations of the auxiliary panels according to this invention. As retractable auxiliary panels are configured at opposite sides of a solar panel, extension of an auxiliary panel refers to its protrusion in front of the plane of solar panel 111. In both configurations shown in FIG. 9A and FIG. 9B, direct beam sunlight 11 irradiates on solar panel 101 from normal incidence (0 degree), and there is no obstruction of its path by auxiliary panels 102T/103T and 102/103. In one embodiment of this invention, auxiliary panels 102T/103T positioned at two sides of a solar panel 101 transmit and redirect additional direct beam sunlight 12/13 to the solar panel. As shown in FIG. 9A, the auxiliary panels 102T and 103T can be substantially curved. In another embodiment of this invention, auxiliary panels 102/103 positioned at two sides of a solar panel 101 reflect and redirect additional sunlight 14/15 to the solar panel. As shown in FIG. 9B, auxiliary panels 102 and 103 can be substantially planar.

As illustrated in FIG. 9B, tilt angles A302 and A303 can be defined for planar auxiliary panels 102 and 103 with reference to the plane of solar panel 111, respectively. The auxiliary panel tilt angle is defined as 0 degree with the auxiliary panel parallel to the solar panel, and 90 degrees with the auxiliary panel perpendicular to the solar panel. Assuming a uniform reflectivity of planar auxiliary panels 102/103, additional sunlight 14/15 reflected off planar auxiliary panels 102/103 is uniform in flux. Angle of incidence for additional sunlight 14/15 on solar panel 101 can be calculated from auxiliary panel tilt angle A302/A303:

angle of incidence of additional sunlight reflected off auxiliary panels on solar panel=2*(90 degrees−auxiliary panel tilt angle with respect to solar panel)

As illustrated in the formula, the incidence angle of the additional sunlight reflected off auxiliary panels onto solar panel increases by two degrees with every one degree reduction in auxiliary panel tilt angle with respect to the solar panel. In one embodiment of this invention, solar panels track the sun and planar reflective auxiliary panels are positioned next to the solar panel with an auxiliary panel tilt angle between 45 and 90 degrees with respect to the plane of solar panel. It can be envisioned from FIG. 9B that in a configuration with an auxiliary panel perpendicular to a solar panel, i.e. at an auxiliary panel tilt angle of 90 degrees, sunlight reflected off the planar auxiliary panel can have a normal incidence on the solar pane, i.e. the angle of incidence is 0 degree. In addition, at an auxiliary panel tilt angle of 45 degrees, sunlight reflected off the auxiliary panel has a glancing incidence on the solar panel, i.e. the angle of incidence is 90 degrees. In order for sunlight reflected off a planar auxiliary panel to intercept a solar panel, the auxiliary panel tilt angle with respect to the solar panel needs to be within 45 and 90 degrees.

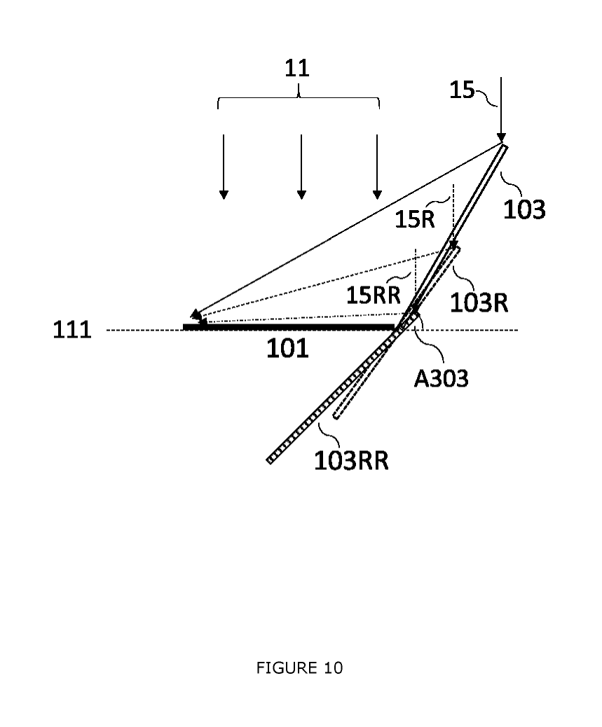

According to this invention, auxiliary panels are retractable. It refers to the portion of auxiliary panels in front of the plane of solar panel 111. In one embodiment of this invention, the retractable auxiliary panels can be rigid. FIG. 10 illustrates retraction of a rigid auxiliary panel 103 positioned at a side of a solar panel 101. As shown in the figure, with a decrease in length of auxiliary panel 103 (to 103R and 103RR) in front of the plane of solar panel 111, the portion of auxiliary panel behind the plane of solar panel 111 can increase. In another embodiment of this invention, PV system has capabilities of controlling not only extension of the auxiliary panels but also auxiliary panel tilt angles with respect to the solar panel. In yet another embodiment of this invention, auxiliary panel tilt angle decreases with a reduction in auxiliary panel extension. It is illustrated in FIG. 10, as auxiliary panel tilt angle A303 decreases with a decrease in extension of auxiliary panel 103 (to 103R and 103RR) in front of the plane of solar panel 111. As shown in the figure, solar irradiations 15/15R/15RR are reflected off planar auxiliary panels 103/103R/103RR, respectively. With a reduction in extension of auxiliary panels, a reduction in auxiliary panel tilt angle with respect to the solar panel 101 is necessary to maintain a uniform coverage of solar irradiation reflected off the planar auxiliary panel onto the entire solar panel 101.

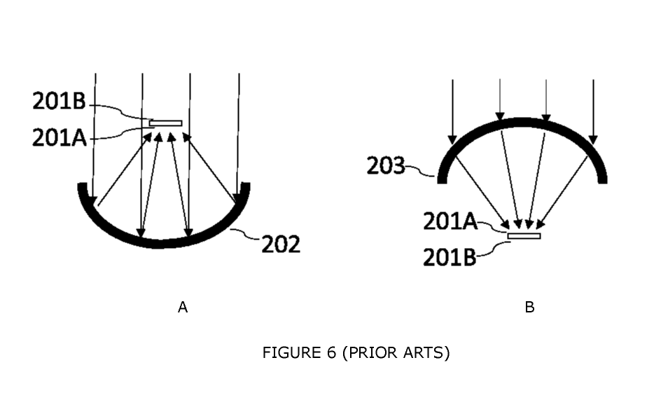

Based on the basic features and functionalities described above, the PV systems according to the present invention are significantly different from conventional concentrator photovoltaic (CPV) systems. In PV systems according to this invention as shown in FIGS. 9-10, the auxiliary panels 102T/103T and 102/103 have no obstruction of the direct sunlight path to the solar panels 101. In comparison, as shown in FIG. 6, solar cells have no line of sight to the sun in conventional CPV systems. In addition, in PV systems according to this invention, the portion of auxiliary panels in front of solar panels can retract, and auxiliary panel tilt angles with respect to the solar panels can also be adjusted. In comparison, the relative configurations between the concentrators (mirrors, lens, etc.) and the collectors (solar cells) are fixed in conventional CPV systems.

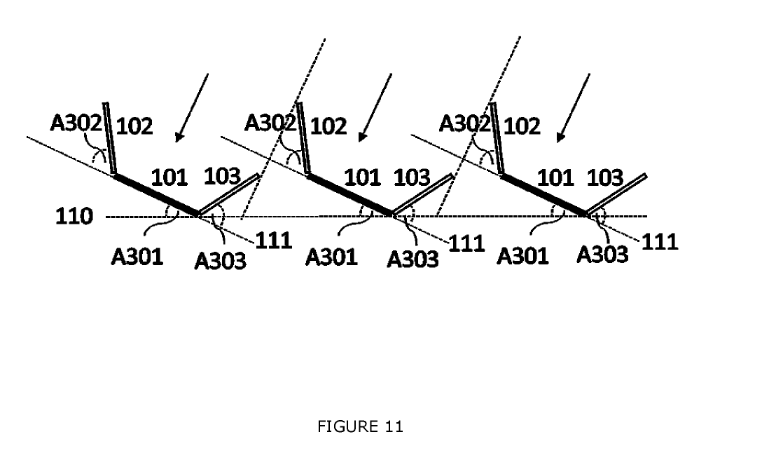

FIG. 11 illustrates a PV system with a plurality of solar panels with planar reflective auxiliary panels according to this invention, with a solar panels tilt angle A301 with respect to ground 110. When the solar panels follow the sun throughout a day, the auxiliary panels can move along. In one embodiment of this invention, the entire auxiliary panel mechanism is mounted on the solar trackers. In another embodiment of the present invention, the mechanical controls of the auxiliary panels can be driven by the same motor to tilt solar panels on the solar trackers. In yet some other embodiments of this invention, the mechanical control of the auxiliary panels is coordinated with that of the solar panels, and such coordination can be achieved via hardware designs or software algorithms.

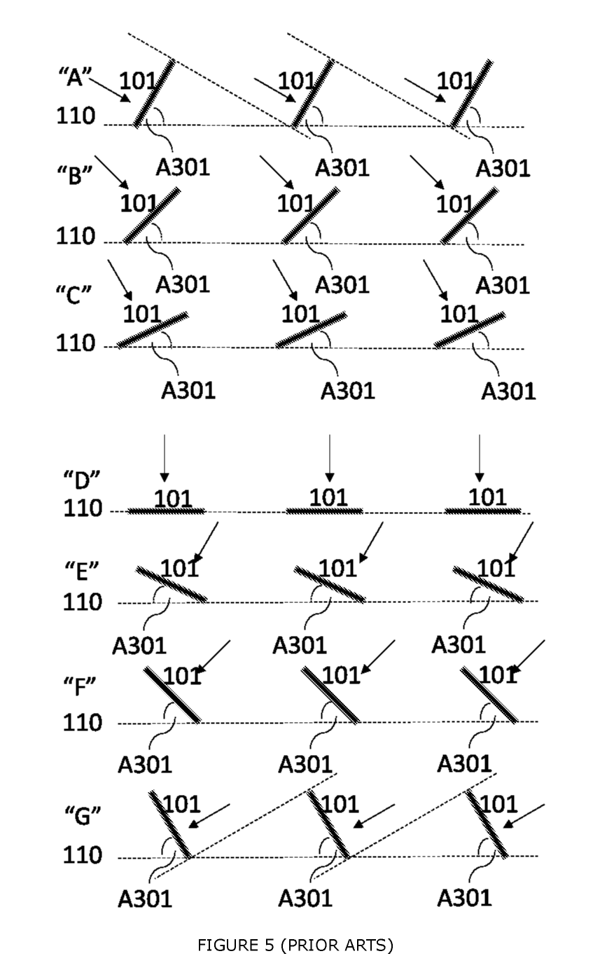

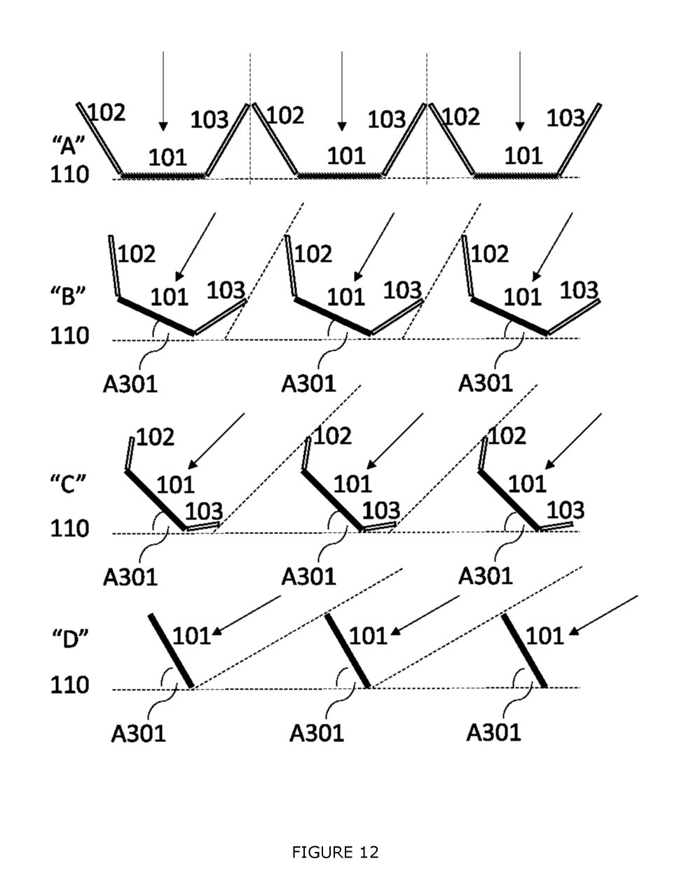

FIG. 12 illustrates a representative algorithm to coordinate auxiliary panel configurations with solar panel tilt angle throughout a day. The PV system shown in FIG. 12 comprises of auxiliary panels positioned at opposite sides of solar panels along its tilt direction on solar trackers, i.e. East-West sides of the solar panels. FIGS. 12“A”-“D” illustrate a progressive change in PV system configurations from noon to late afternoon. The PV system configurations in the morning can be merely mirror images, thus are omitted in FIG. 12. Compared with the conventional PV system in absence of auxiliary panels as shown in FIG. 5, the PV system shown in FIG. 12 has the same maximum solar panel tilt angle and the same spacing between adjacent solar panels, i.e. system ground coverage ratio. In addition, solar panel tilt angle A301 matches between configurations illustrated in FIG. 12“A” and FIG. 5“D”, FIG. 12“B” and FIG. 5“E”, FIG. 12“C” and FIG. 5“F”, FIG. 12“D” and FIG. 5“G”, respectively.

As discussed in Background of the Invention section, it is important to have adequate spacing between adjacent rows or arrays of solar panels mounted on solar trackers to avoid shading on adjacent solar panels when solar panels tilt to track the Sun throughout a day. In PV systems according to this invention, auxiliary panels can be positioned at opposite sides of solar panels on solar trackers with no increase in spacing between adjacent rows or arrays of solar panels. As shown in FIGS. 9 and 10, uniform solar direct irradiation 11 is not obstructed by auxiliary panels 102T/103T and 102/103 positioned at opposite sides of the solar panels. In addition, as illustrated in FIG. 10, additional solar irradiation 15(15R/15RR) reflected off planar auxiliary panel 103(103R/103RR) can have a uniform coverage over the entire solar panel with a coordination of extension and tilt angle of planar reflective auxiliary panels with respect to the solar panels. Finally, with a progressive change in solar panel tilt angle throughout a day, configurations of auxiliary panels can be adjusted accordingly to avoid shading on adjacent solar panels. In one embodiment of this invention, at least one of the planar auxiliary panels positioned next to a solar panel retracts with an increase in solar panel tilt angle. In another embodiment of this invention, tilt angle of at least one of the planar auxiliary panels with respect to the solar panel decreases with an increase in solar panel tilt angle. In yet another embodiment of this invention, at least one of the planar auxiliary panels positioned next to a solar panel retracts and its tilt angle with respect to the solar panel decreases at the same time with an increase in solar panel tilt angle. As shown in FIG. 12, with a retraction of auxiliary panels in front of the solar panels, shading of adjacent solar panels can be avoided even at a significant solar panel tilt angle.

In one embodiment of the present invention, the two auxiliary panels at opposite sides of a solar panel can have identical configurations, i.e. symmetric in configuration with reference to the solar panel in between. As shown in FIG. 12, configurations of the auxiliary panels can change at different solar panel tilt angles throughout a day, yet remain symmetric relative to the solar panel in between. Limiting auxiliary panels at opposite sides of solar panels to symmetric configurations may simplify the system mechanical design and control algorithm.

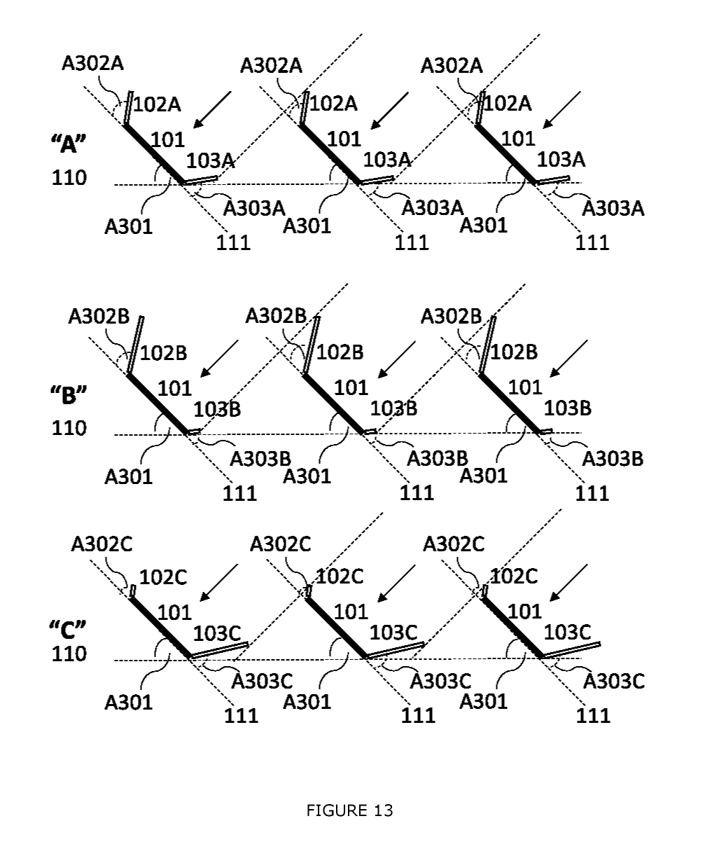

In another embodiment of the present invention, PV systems according to this invention, auxiliary panels at opposite sides of solar panels can adopt asymmetric configurations with respect to solar panels in between. FIGS. 13“A”-“C” compares three different PV system configurations with the same solar panel tilt angle A301 and the same spacing between solar panels 101, i.e. ground coverage ratio. FIG. 13“A” illustrates a symmetric configuration of auxiliary panels 102A and 103A with respect to solar panel 101, i.e. auxiliary panels 102A and 103A have the same extensions and corresponding auxiliary panel tilt angles A302A and A303A are also identical. In comparison, FIG. 13 “B” and “C” illustrate a couple of asymmetric auxiliary panel configurations with respect to solar panel 101. In the PV system shown in FIG. 13“B”, auxiliary panel at the left side (higher side of solar panels) 102B has the longer extension than the auxiliary panel at the right side (lower side of solar panels) 103B. In the PV system shown in FIG. 13“C”, the auxiliary panel at the right side (lower side of solar panels) 103C is longer than the auxiliary panel at the left side (higher side of solar panels) 102C instead. As discussed above, it is important to have a uniform coverage of the additional sunlight reflected off planar auxiliary panels onto the solar panel, e.g. by coordinating a reduction of auxiliary panel extension with a reduction in corresponding auxiliary panel tilt angle with respect to the solar panel. Consequently, in PV system configuration illustrated in FIG. 13“B”, the left side (higher side of solar panels) auxiliary panel tilt angle A302B is larger than the right side (lower side of solar panels) auxiliary panel tilt angle A302C. In PV system configuration illustrated in FIG. 13“C”, the right side (lower side of solar panels) auxiliary panel tilt angle A303C is larger than the left side (higher side of solar panels) auxiliary panel tilt angle A303B instead. In comparison, auxiliary panel tilt angles A302A and A303A are the same in the symmetric configuration shown in FIG. 13“A”. It can be envisioned that auxiliary panel tilt angles A302A and A303A are smaller than auxiliary panel tilt angles A302B and A303C but are larger than auxiliary panel tilt angles A302C and A303B.

Three PV system configurations shown in FIGS. 13 “A”-“C” have the same ground coverage ratio, thus the same total amount of solar panels over a land area. The three PV system configurations also have the same solar panel tilt angle to follow the Sun, thus have the same amount of unobstructed solar irradiation from normal incidence onto the solar panels 101. The remainder of direct solar irradiation over the land area is reflected off auxiliary panels 102A and 103A, 102B and 103B, 102C and 103C and onto solar panels 101 in FIGS. 13“A”-“C”, respectively. As a result, the three PV system configurations shown in FIGS. 13“A”-“C” also have the same total amount of additional solar irradiation reflected off auxiliary panels and onto solar panels. However, symmetric configuration of auxiliary panels shown in FIG. 13“A” and asymmetric configurations of auxiliary panels shown in FIGS. 13“B”-“C” can have different AOIs of the reflected solar irradiation onto the solar panels. As discussed above, there is a direct relationship between extension of auxiliary panel and auxiliary panel tilt angle. Furthermore, there is an inverse relationship between auxiliary panel tilt angle and AOI of the reflected solar irradiation onto the solar panels. In the symmetric configuration of auxiliary panels as shown in FIG. 13“A”, auxiliary panels 102A and 103A reflect equal amount of solar irradiation. Auxiliary panel tilt angles A302A and A303A are equivalent, so are AOIs of solar irradiation reflected off auxiliary panels 102A and 103A onto solar panel 101. In the asymmetric configurations of auxiliary panels as shown in FIGS. 13“B” and 13“C”, auxiliary panels 102B in FIG. 13“B” and auxiliary panels 103C in FIG. 13“C” are longer than the auxiliary panels at the other side of the solar panels, i.e. auxiliary panels 102C in FIG. 13“B” and auxiliary panels 103B in FIG. 13“C”. In addition, auxiliary panels 102B in FIG. 13“B” and auxiliary panels 103C in FIG. 13“C” are also longer than auxiliary panels 102A and 103A in FIG. 13“A”. As a result, corresponding auxiliary panel tilt angle A302B in FIG. 13“B” and auxiliary panel tilt angle A303C in FIG. 13“C” are larger than auxiliary panel tilt angles A302A and A303A in FIG. 13“A”. As a result, solar irradiation reflected off auxiliary panels 102B in FIG. 13“B” and auxiliary panels 103C in FIG. 13“C” has a smaller AOI on solar panels 101 in comparison with AOI of solar irradiation reflected off auxiliary panels 102A and 103A in the symmetric configuration of auxiliary panels in FIG. 13“A”. Overall, as predominant amount of the additional solar irradiation is reflected off auxiliary panels of the longer extension in asymmetric configurations of auxiliary panels, total solar irradiation reflected off auxiliary panels can have a smaller AOI onto solar panels in comparison with that in a symmetric configuration of auxiliary panels. As discussed in Background of the Invention section, solar panel efficiency can be a function of AOI of solar irradiation under the same irradiation intensity, e.g. silicon solar panel efficiency can decrease significantly with an increase of AOI at >60 degrees. Three configurations of auxiliary panels shown in FIGS. 13“A”-“C” yield the same total amount of solar irradiation on solar panels 101. However, asymmetric configurations shown in FIGS. 13“B”-“C” yield a smaller AOI of solar irradiation reflected off auxiliary panels onto solar panels, which can result in a higher overall solar panel efficiency en route to a higher PV system electricity generation.

PV systems comprising auxiliary panels according to this invention can collect maximum direct beam sunlight onto solar panels. Planar reflective auxiliary panels according to this invention can also redirect additional diffuse sunlight to solar panels, in both cloudy and clear days. As discussed in Background of the Invention section, the diffuse sunlight accounts for ˜10% of total solar energy in clear days, and its portion can significantly increase in cloudy days. In conventional PV systems on solar trackers, solar panels are parked at the horizontal position in cloudy days in a configuration analogous to that shown in FIG. 5“D”, and diffuse sunlight collection onto solar panels is limited by system ground coverage ratio. In addition, much of the diffuse sunlight has a significant angle of incidence (AOI) on the solar panels. As a result, overall system energy generation in cloudy days is very low. In PV systems with auxiliary panels according to this invention, a configuration analogous to that shown in FIG. 12A can be adopted in cloudy days. Solar panels can be positioned horizontally with auxiliary panels fully extended at opposite sides of solar panels. The auxiliary panels can redirect additional diffuse sunlight to the solar panels, and reduce the overall angle of incidence (AOI). Consequently, PV system energy production in cloudy days can be improved.

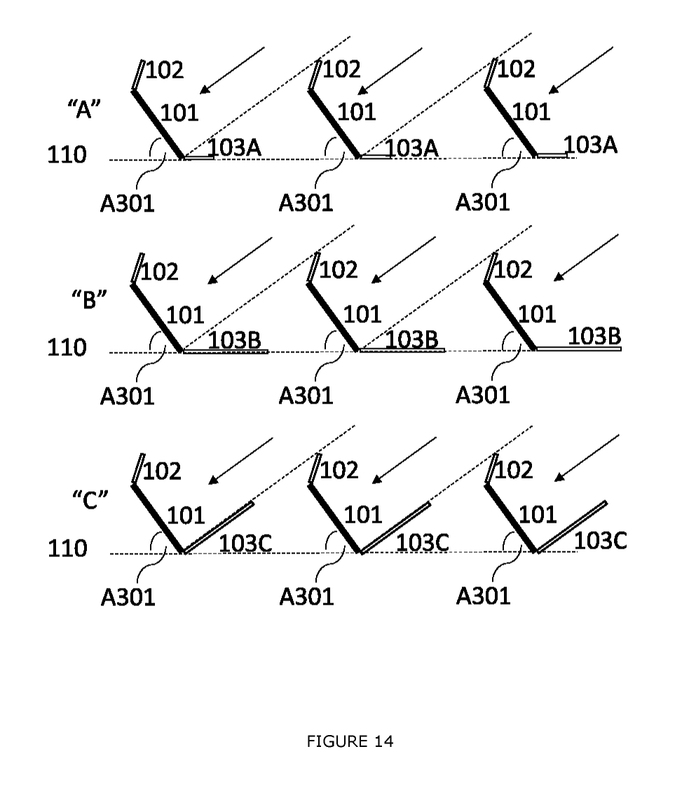

In clear days, auxiliary panels in this invention are configured primarily to maximize collection of direct beam Sunlight on the solar panels. Nevertheless, the auxiliary panels can still redirect some additional diffuse sunlight to the solar panels at the same time. In addition, in some configurations one of the two auxiliary panels at sides of a solar panel can be completed out of sight from the Sun, and its configuration can be optimized to maximize diffuse sunlight collection onto the solar panels. Three of these configurations are shown in FIG. 14. As shown in the figure, solar panels 101 are significantly tilted to track the sun, and planar reflective auxiliary panels at the left side (higher side of solar panels) 102 are configured to capture direct sunlight beam without casting shadows on adjacent solar panels 101. On the other hand, the auxiliary panels at the right side (lower side of solar panels) 103A/103B/103C are completely out of sight from the sun in FIGS. 14“A”-“C”, respectively. They can be configured to reflect diffuse sunlight to the solar panels 101. FIG. 14“A” illustrates a symmetric configuration of auxiliary panels with respect to solar panels 101. In comparison, FIGS. 14“B”-“C” illustrate two asymmetric configurations, in which the right auxiliary panels 103B in FIGS. 14“B” and 103C in FIG. 14“C” have longer extensions than the left auxiliary panels 102. Furthermore, the right auxiliary panels 103C in FIG. 14“C” are configured perpendicular to the solar panels 101 to maximize collection of diffuse sunlight onto the solar panels 101.

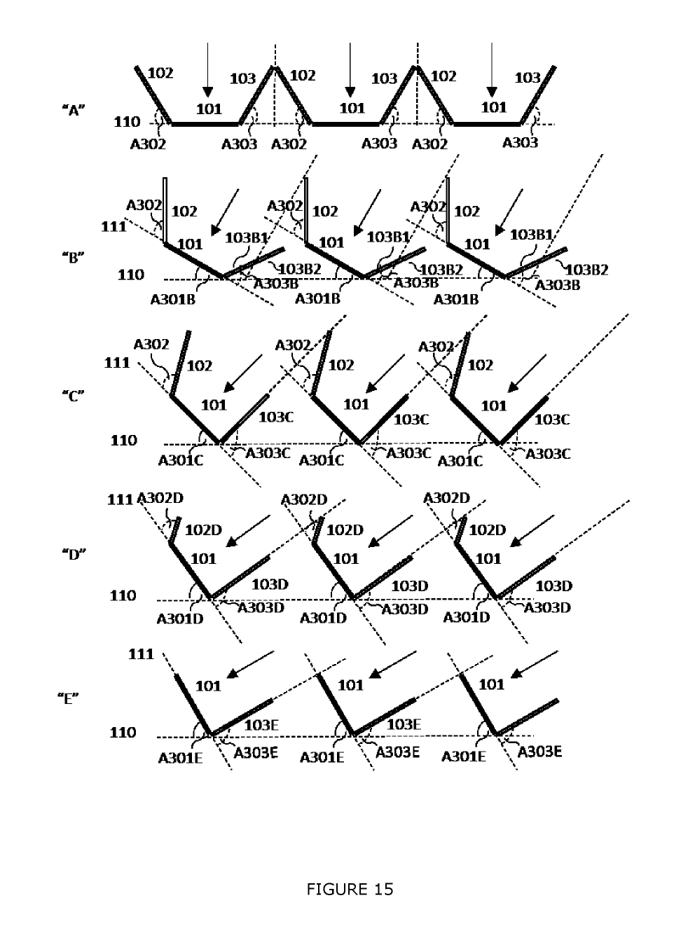

In clear days, auxiliary panels configuration can be changed throughout a day to collect maximum direct beam and extra diffuse sunlight at the same time. FIG. 15 illustrates an algorithm to operate a PV system on solar trackers with planar reflective auxiliary panels according to several embodiments in this invention. The configurations from noon to late afternoon are included in the figure, with solar panels tilt to track the sun. As shown in FIG. 15“A”, it is conceivable to position solar panels 101 horizontally with a symmetric configuration of auxiliary panels 102/103 at opposite sides of solar panels 101 around noon time. The fully extended auxiliary panels 102 and 103 are under direct solar irradiation and reflect direct beam and diffuse sunlight onto solar panels 101. The entire PV system on solar trackers starts to tilt to right in FIG. 15“B”. In an embodiment of this invention, auxiliary panels at the left side (the higher side of solar panels) 102 maintain the maximum extension. The full length of the auxiliary panels 102 remain under direct solar irradiation, and there is no change in corresponding auxiliary panel tilt angle A302 with respect to solar panels 101. At the same time, although auxiliary panels at the lower side (right side) of solar panels are also fully extended, only part of the auxiliary panels 103B1 has line of sight to the sun. The rest of the right auxiliary panels 103B2 is out of direct line-of-sight from the sun, but can redirect some diffuse sunlight to the solar panels 101. With the reduced length of the right side (lower side of solar panels) auxiliary panels under direct solar irradiation, the corresponding auxiliary panel tilt angle A303B with respect to solar panels 101 decreases to maintain a uniform coverage of direct beam sunlight reflected off the auxiliary panels on the solar panels 101. With solar panel tilt angle continues to increase into afternoon, auxiliary panels at the left side (higher side of solar panels) 102 can maintain their extension and corresponding auxiliary panel tilt angle can remain the same until a threshold PV system configuration shown in FIG. 15“C”. As shown in FIG. 15“C”, at a solar panel tilt angle of A301C, auxiliary panels at the right side (lower side of solar panels) 103C are completely out of light from the sun. A further increase in solar panel tilt angle requires auxiliary panels at the higher side (left side) of solar panels to retract in order to prevent shading on adjacent solar panels. As illustrated in FIG. 15“D”, with a reduction in extension of auxiliary panels at the left side (higher side of solar panels) 102D, auxiliary panel tilt angle A302D decreases accordingly. As illustrated in FIG. 15“E”, auxiliary panels at the higher side (left side) of solar panels can be fully retracted at a maximum solar panel tilt angle of A301E. Meanwhile, once the solar panel tilt angle reaches and exceeds the threshold angle of A301C as shown in FIG. 15“C”, the auxiliary panels at the right side (lower side of solar panels) 103C/103D/103E are completely out of sight from the sun, as illustrated in FIGS. 15“C”-“E”, respectively. To maximize diffuse sunlight collection onto solar panels 101, the right auxiliary panels 103C/103D/103E can be fully extended and oriented perpendicular to the solar panels 101 in FIGS. 15“C”-“E”, respectively.

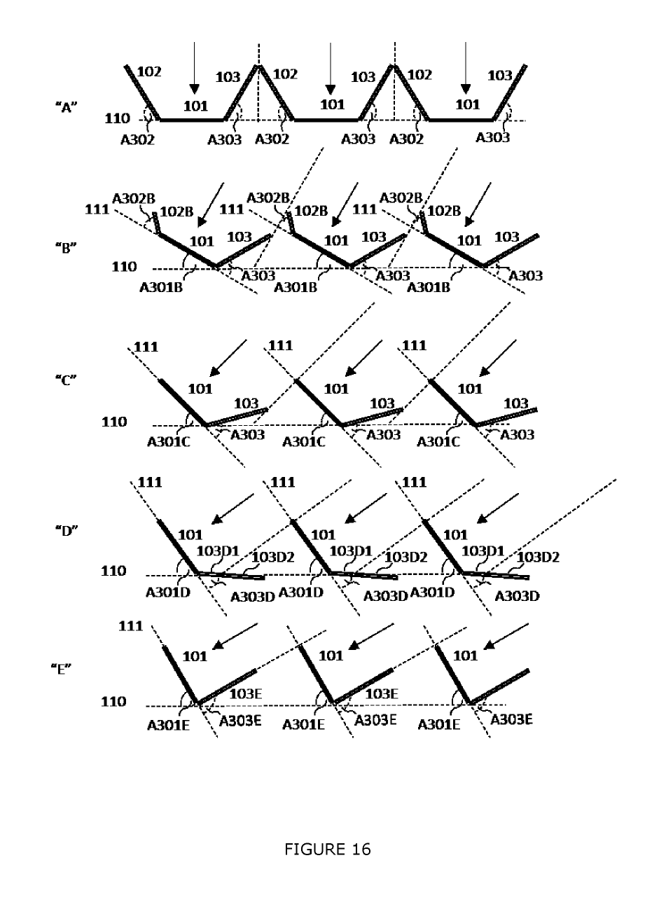

FIG. 16 illustrates another algorithm to operate a PV system on solar trackers with planar reflective auxiliary panels according to several embodiments in this invention. Solar panels 101 tilt and follow the Sun from noon to late afternoon in PV system configurations illustrated in FIG. 16, analogous to those shown in FIG. 15. In addition, PV systems illustrated in FIGS. 15 and 16 have the same ground coverage ratio, and solar panel tilt angle is the same between PV system configurations shown in FIGS. 15“A” and 16“A”, FIGS. 15“B” and 16“B”, FIGS. 15“C” and 16“C”, FIGS. 15“D” and 16“D”, FIGS. 15“E” and 16“E”, respectively. At the same solar panel tilt angle, the auxiliary panel configurations in FIGS. 15 and 16 are identical at zero solar panel tilt angle (FIGS. 15“A” and 16“A” at noon time) and at maximum solar panel tilt angle A301E (FIGS. 15“E” and 16“E”). However, auxiliary panel configurations are different between FIGS. 15 and 16 at other solar panel tilt angles in between, i.e. between FIGS. 15“B” and 16“B”, 15“C” and 15“C”, and 15“D” and 16“D”, respectively. It is conceivable to have auxiliary panels 102/103 at opposite sides of solar panels 101 fully extended at noon time, as illustrated in FIG. 16“A”. In the PV system configuration illustrated in FIG. 16“B”, solar panels 101 tilt to right to track the sun, and auxiliary panels at the right side (lower side of solar panels) 103 maintain at fully extension. In addition, there is no change in corresponding auxiliary panel tilt angle (with respect to solar panels) A303. At the same time, auxiliary panels at the left side (higher side of solar panels) 102B retract, and left auxiliary panel tilt angle A302B decreases accordingly. In the PV system configuration shown in FIG. 16“C”, while there is no change to extension of auxiliary panels at the lower side (right side) of solar panels and corresponding auxiliary panel tilt angle, auxiliary panels at the higher side (left side) of solar panels can be fully retracted at a threshold solar panel tilt angle A301C. Solar panel tilt angle A301D further increases in the PV configuration shown in FIG. 16“D”. Auxiliary panels at the higher side (left side) of solar panels are still fully retracted, and auxiliary panels at the lower side (right side) of solar panels are still fully extended. However, only portion of the auxiliary panels at the right side (lower side of solar panels) has line of sight to the sun 103D1 and the rest 103D2 is out of sight from the sun. The corresponding auxiliary panel tilt angle A303D decreases to main a uniform coverage of direct beam solar irradiation reflected off portion of right auxiliary panels with line-of-sight to the Sun 103D1 onto solar panels 101.

It is useful to compare progression of PV system configurations illustrated in FIG. 16 versus the configurations shown in FIG. 15. Comparing configurations shown in FIGS. 15“B” and 16“B”, auxiliary panels at the left side (higher side of solar panels) 102 in FIG. 15“B” have the same extension as auxiliary panels at the right side (lower side of solar panels) 103 in FIG. 16“B”. Corresponding auxiliary panel tilt angle A302 in FIG. 15“B” is also the same as corresponding auxiliary panel tilt angle A303 in FIG. 16“B”. In addition, portion of auxiliary panels at the right side (lower side of solar panels) with line-of-sight to the sun 103B-1 in FIG. 15“B” has the same extension as auxiliary panels at the left side (higher side of solar panels) 102B in FIG. 16“B”. Corresponding auxiliary panel tilt angle A303B in FIG. 15“B” is also the same as corresponding auxiliary panel tilt angle A302B in FIG. 16“B”. As a result, FIGS. 15“B” and 16“B” have the same total amount of direct beam solar irradiation with the same angle of incidence (AOI) on the solar panels. Meanwhile, there is some difference between PV system configurations shown in FIGS. 15“B” and 16“B”. In comparison, the PV system configuration shown in FIG. 15“B” has an extra length of auxiliary panel at the right side (lower side of solar panels) out of sight from the sun 103B-2, which can redirect more diffuse sunlight to solar panels 101. On the other hand, the PV system configuration shown in FIG. 16“B” has a shorter extension of auxiliary panels at the higher side (left side) of solar panels, thus has a lower system height and potentially a smaller system wind load.

In a similar manner, PV configurations illustrated in FIGS. 16“C” and 16“D” can be compared with those shown in FIGS. 15“C” and 15“D”, respectively. Again at the same solar panel tilt angle, corresponding PV configurations shown in FIGS. 15 and 16 collect the same amount of direct beam sunlight on solar panels 101 with the same AOI. However, PV system configurations shown in FIGS. 16“C”-“D” can have system heights lower than those of the PV system configurations shown in FIGS. 15“C”-“D”, respectively. On the other hand, PV system configurations shown in FIGS. 15“C”-“D” can collect more diffuse sunlight onto solar panels 101 in comparison with PV system configurations shown in FIGS. 16“C”-“D”, respectively.

What is claimed is:

1. A photovoltaic apparatus comprising:
a substantially planar solar panel having a front side, a back side, and at least two opposite edges;
a first mechanism for tilting the solar panel, wherein the tilt angle of the solar panel is substantially 0 degree when the solar panel is substantially parallel to the around and the tilt angle of the solar panel is substantially 90 degrees when the solar panel is substantially perpendicular to the ground;
at least two auxiliary panels, wherein a first auxiliary panel is positioned near one edge of the solar panel and a second auxiliary panel is positioned near the opposite edge of the solar panel, wherein the auxiliary panels are capable of directing solar irradiation towards the solar panel;
a second mechanism for adjusting the auxiliary panels, wherein the auxiliary panels can be adjusted to extend or retract with respect to the front side of the solar panel.

2. A photovoltaic apparatus according to claim 1, wherein said auxiliary panels do not obstruct sunlight direct beam to the solar panel.

3. A photovoltaic apparatus according to claim 1, wherein at least one of said auxiliary panels transmits said solar irradiation.

4. A photovoltaic apparatus according to claim 1, wherein at least one of said auxiliary panels reflects said solar irradiation.

5. A photovoltaic apparatus according to claim 1, wherein at least one of said auxiliary panels is substantially planar.

6. A photovoltaic apparatus according to claim 1, wherein at least one of said auxiliary panels is substantially rigid.

7. A photovoltaic apparatus according to claim 1, wherein said first mechanism can adjust the tilt angle of the solar panel in one direction.

8. A photovoltaic apparatus according to claim 1, wherein said first mechanism can adjust the tilt angle of the solar panel in one direction and said auxiliary panels are positioned at opposite sides of the solar panel at the direction to adjust the tilt angle of the solar panel.

9. A photovoltaic apparatus according to claim 1, wherein said first mechanism can adjust the tilt angle of the solar panel in two directions.

10. A photovoltaic apparatus according to claim 1, wherein said second mechanism can further adjust the tilt of the auxiliary panels with respect to the front side of the solar panel.

11. A photovoltaic apparatus according to claim 1, wherein said first mechanism and said second mechanism are controlled by a common motor.

12. A photovoltaic apparatus according to claim 1, wherein said first mechanism and said second mechanism are coordinated by software.

13. A photovoltaic apparatus according to claim 1, wherein at least one of said auxiliary panels is not receiving any direct sunlight but directing diffuse sunlight to said solar panel in electricity generation.

14. A photovoltaic apparatus according to claim 1, wherein at least one of said auxiliary panels has a first part with line of sight to the sun and a second part not receiving any direct sunlight but directing diffuse sunlight to said solar panel in electricity generation.

15. A photovoltaic apparatus according to claim 1, wherein at least one of said auxiliary panels is substantially planar and said second mechanism can further adjust the tilt of the auxiliary panel with respect to the solar panel, wherein the tilt angle of the auxiliary panel is substantially 0 degree when the auxiliary panel is substantially parallel to the solar panel and the tilt angle of the auxiliary panel is substantially 90 degrees when the auxiliary panel is substantially perpendicular to the solar panel.

16. A photovoltaic apparatus according to claim 1, wherein at least one of said auxiliary panels is substantially planar and said second mechanism can further adjust the tilt of the auxiliary panel with respect to the solar panel, wherein the tilt angle of the auxiliary panel is substantially 0 degree when the auxiliary panel is substantially parallel to the solar panel and the tilt angle of the auxiliary panel is substantially 90 degrees when the auxiliary panel is substantially perpendicular to the solar panel; and
wherein the tilt angle of said substantially planar auxiliary panel is between 45 degrees and 90 degrees in electricity generation.

17. A photovoltaic apparatus according to claim 1, wherein at least one of said auxiliary panels is substantially planar and said second mechanism can further adjust the tilt of the auxiliary panel with respect to the solar panel, and wherein at least one of said substantially planar auxiliary panels is not receiving any direct sunlight but directing diffuse sunlight to said solar panel in electricity generation.

18. A photovoltaic apparatus comprising:
a substantially planar solar panel having a front side, a back side, and at least two opposite edges;
a first mechanism for tilting the solar panel, wherein the tilt angle of the solar panel is substantially 0 degree when the solar panel is substantially parallel to the around and the tilt angle of the solar panel is substantially 90 degrees when the solar panel is substantially perpendicular to the ground;
at least two auxiliary panels, wherein a first auxiliary panel is positioned near one edge of the solar panel and a second auxiliary panel is positioned near the opposite edge of the solar panel, wherein the auxiliary panels are substantially planar and are capable of reflecting solar irradiation towards the solar panel;
a second mechanism for adjusting the auxiliary panels to extend or retract and to tilt with respect to the front side of the solar panel, wherein the tilt angle of the auxiliary panel is substantially 0 degree when the auxiliary panel is substantially parallel to the solar panel and the tilt angle of the auxiliary panel is substantially 90 degrees when the auxiliary panel is substantially perpendicular to the solar panel.

19. A photovoltaic apparatus according to claim 18, wherein the tilt angle of said substantially planar auxiliary panel is between 45 degrees and 90 degrees.

20. A photovoltaic apparatus comprising:
a substantially planar solar panel having a front side, a back side, and at least two opposite edges;
a first mechanism for tilting the solar panel at the direction between the two opposite edges, wherein the tilt angle of the solar panel is substantially 0 degree when the solar panel is substantially parallel to the ground and the tilt angle of the solar panel is substantially 90 degrees when the solar panel is substantially perpendicular to the ground;
at least two auxiliary panels, wherein a first auxiliary panel is positioned near one edge of the solar panel and a second auxiliary panel is positioned near the opposite edge of the solar panel, wherein the auxiliary panels are substantially planar and are capable of reflecting solar irradiation towards the solar panel;
a second mechanism for adjusting the auxiliary panels to extend or retract and to tilt with respect to the front side of the solar panel, wherein the tilt angle of the auxiliary panel is substantially 0 degree when the auxiliary panel is substantially parallel to the solar panel and the tilt angle of the auxiliary panel is substantially 90 degrees when the auxiliary panel is substantially perpendicular to the solar panel.
